(19) United States
(12) Patent Application Publication
(10) Pub. No.: US 2025/0066597 A1
(43) Pub. Date: Feb. 27, 2025

(54) POLYMER CAPACITIVE SENSORS AND METHODS OF USES THEREOF

(71) Applicant: UNIVERSITY OF OTTAWA, Ottawa (CA)

(72) Inventors: Benoît Hugo LESSARD, Ottawa (CA); Mathieu Neil TOUSIGNANT, Ottawa (CA)

(73) Assignee: UNIVERSITY OF OTTAWA, Ottawa, ON (CA)

(21) Appl. No.: 18/721,325

(22) PCT Filed: Aug. 19, 2022
(86) PCT No.: PCT/CA2022/000047

§ 371 Date: Jun. 18, 2024

Related U.S. Application Data
(60) Provisional application No. 63/291,751, filed on Dec. 20, 2021.

(51) Int. Cl. C08L 29/04; C08L 67/04; H01G 4/14; H10K 10/46; H10K 85/20

(52) U.S. Cl. CPC C08L 29/04; C08L 67/04; H01G 4/14; H10K 10/466; H10K 10/474; H10K 10/484; H10K 85/221; C08L 2201/06; C08L 2203/20; C08L 2312/00

(57) ABSTRACT

A polymer dielectric is described comprising a multi-layered structure containing at least two different dielectric materials. The dielectric materials comprise biodegradable organic dielectric materials. and in certain embodiments are crosslinked at an interface of the deposited dielectric materials. Organic thin-film transistors (OTFT) and capacitors comprising this multi-layered structure are also described. as well as methods for crosslinking the dielectric materials.

### FIELD OF INVENTION

The present invention relates to printed electronics such as polymer capacitors, capacitive sensors and dielectric for transistors, particularly those containing multi-layered dielectrics.

### BACKGROUND OF THE INVENTION

As the manufacturing cost of electronic devices decreases, the potential for emerging applications increases, such as the use of smart packaging. Some examples of these applications include the incorporation of electronic sensors within product packaging, such as radio-frequency identification (RFID) tags that enable consumers to access supplemental product information or temperature sensors to alert distributors and consumers that a product has been exposed to unsafe temperatures.

Smart packaging has quickly become a multi-billion-dollar industry, with the potential to dramatically reduce food waste and improve consumer experience and confidence. However, for smart packaging to be viable, the electronically active materials need to be environmentally friendly to reduce the footprint of the waste created, inexpensive, amenable to low-cost printing processes, and suitable for a variety of implementations. Additionally, the electronically active materials should provide a high dielectric constant (high-k), low leakage current, and no hysteresis.

Organic thin film transistors (OTFTs) and capacitors offer potential sources for smart packaging. OTFTs and capacitors are capable of detecting and signaling changes to a variety of conditions. OTFTs and capacitors are generally comprised of multiple layers (having various thicknesses), including electrodes, a semiconductor, and a dielectric. The dielectric can be classified into two main categories: organic or inorganic.

Organic (carbon based) dielectrics, or polymer dielectrics, have the potential to yield flexible and biodegradable devices through low-temperature and solution processing techniques, however these dielectrics typically suffer from higher leakage currents, a larger number of defects, and lower capacitances. These restrictions limit their ability to be utilized in a variety of applications, and decrease their overall performance.

Inorganic dielectrics, meanwhile, have lower leakage currents with well characterized performance metrics, but these materials require higher processing temperatures, higher operating voltages, and are not amenable to printing processes or many flexible applications.

Existing organic dielectrics used in OTFTs are not suitable for use in smart packaging. For example, poly (methyl methacrylate), poly (vinyl phenol), and poly (styrene) are undesirable for smart packaging as they are non-biodegradable. These OTFTs are further unsuitable for use in smart packaging due to low-k and low capacitance densities. Meanwhile organic dielectrics such as poly (vinyl alcohol) (PVA), a relatively high-k dielectric that is water soluble and environmentally friendly, is moisture sensitive and suffers from large leakage currents, poor film forming capabilities, and large hysteresis.

These limitations prevent wide-spread applicability of OTFTs and capacitors, due to

the expense and limitations in manufacturing, or the negative impact on the environment from introducing further non-biodegradable products into the product chain.

As such, there exists a need for an OTFT and capacitors that utilizes a dielectric that is biodegradable, high-k, exhibits low leakage current, and no hysteresis, while also being amenable to a variety of processing techniques, preferably in an environmentally friendly manner.

### SUMMARY OF THE INVENTION

An object of the invention is to provide a polymer dielectric comprising a multi-layered structure containing at least two different dielectric materials, as well as organic thin-film transistors (OTFT) and capacitors comprising this multi-layered structure, and methods for crosslinking the dielectric materials.

According to an aspect of the invention described herein, there is provided a polymer dielectric comprising a multi-layered structure containing at least two different dielectric materials, wherein the dielectric materials comprise biodegradable organic dielectric materials.

In certain non limiting embodiments of the polymer dielectric, the polymer dielectric may contain two or three different dielectric materials.

In further non limiting embodiments of the polymer dielectric, the multi-layered dielectric may contain at least one low-k dielectric material and at least one high-k dielectric material.

In further non limiting embodiments of the polymer dielectric, the biodegradable organic dielectric materials may be crosslinked at an interface of the material interface.

In further non limiting embodiments of the polymer dielectric, the dielectric may comprise a capacitor or transistor, or a polymer capacitive sensor.

According to another aspect of the invention described herein, there is provided an organic thin-film transistor (OTFT) comprising:
a. a substrate component;
b. a gate component;
c. a multi-layered dielectric component;
d. a source component; and
e. a drain component.

According to yet another aspect of the invention described herein, there is provided a capacitor comprising:
a. a substrate component;
b. a bottom electrode component;
c. a multi-layered dielectric component; and
d. a top electrode component.

In certain non limiting embodiments of the OTFT or capacitor described herein, the

multi-layered dielectric component may be comprised of at least two different dielectric materials;

In further non limiting embodiments of the OTFT or capacitor described herein, the multi-layered dielectric component may be comprised of at least one high-k dielectric material and at least one low-k dielectric material.

In other non limiting embodiments of the OTFT or capacitor described herein, the multi-layered dielectric component may consist of only organic dielectric materials;

In further non limiting embodiments of the OTFT or capacitor described herein, the multi-layered dielectric component may consist of only biodegradable materials;

In additional non limiting embodiments of the OTFT or capacitor described herein, the multi-layered dielectric component may comprise:
a. a poly (vinyl alcohol)/cellulose nanocrystal blended dielectric (PVAc) layer deposited above the gate component or the substrate component; and
b. a toluene diisocyanate-terminated polycaprolactone (TPCL) layer deposited above the PVAc layer.

In other non limiting embodiments of the OTFT or capacitor described herein, the PVAc layer and TPCL may be thermally cross-linked to one another.

In yet further non limiting embodiments of the OTFT or capacitor described herein, the multi-layered dielectric component may comprise:
a. a poly (vinyl alcohol)/cellulose nanocrystal blended dielectric (PVAc) layer, having a first surface and a second surface;
b. a toluene diisocyanate-terminated polycaprolactone (TPCL) layer disposed at said first surface; and
c. a poly (lactic acid) (PLA) layer disposed at said second surface.

In non limiting embodiments of the OTFT or capacitor described above, the TPCL layer may be deposited above the PVAc layer, and the PVAc layer deposited above the PLA layer.

In yet other non limiting embodiments of the OTFT or capacitor described herein, the PVAc layer and TPCL may be thermally cross-linked to one another.

According to yet another aspect of the invention described herein, there is provided a method for preparing a multi-layer dielectric for an organic thin-film transistor (OTFT) or capacitor, wherein:
a high-k dielectric material layer is deposited above a gate component or a substrate component of the OTFT or capacitor;
a low-k dielectric material layer is deposited above the high-k dielectric material layer; and
the low-k dielectric material is crosslinked with the high-k dielectric material.

In non limiting embodiments of the described method, the high-k dielectric material may be a poly (vinyl alcohol)/cellulose nanocrystal blended dielectric (PVAc) and the low-k dielectric material may be a toluene diisocyanate-terminated polycaprolactone (TPCL), and the TPCL layer is crosslinked with the PVAc material via hydroxyl groups of the PVAc material.

In further non limiting embodiments of the described method, the low-k dielectric material layer may be crosslinked on top of the high-k dielectric material at a layer interface after deposition.

In yet further non limiting embodiments, the crosslinking temperature is carried out at or above crosslinking temperatures, and below a decomposition temperature of the specific polymer used. For example, in non limiting embodiments the crosslinking may be carried out at from 150° C. to 350° C., more preferably from 150° C. to 250° C. In yet other non limiting embodiments of the described method, the crosslinking may be carried out at about 200° C.

### BRIEF DESCRIPTION OF THE DRAWINGS

These and other features of the invention will become more apparent from the following description in which reference is made to the appended drawings wherein:

FIG. 1 shows (a) a dielectric based OTFT structure, (b) a bi-layered dielectric based OTFT structure, and (c) a tri-layered dielectric based OTFT structure, in accordance with embodiments of the present invention

FIG. 2 shows a shows (a) a dielectric based capacitor structure; (b) a bi-layered dielectric based capacitor structure, and (c) a tri-layered dielectric based capacitor structure, in accordance with embodiments of the present invention

FIG. 3 shows measurements of dielectric constant and capacitance density for dielectric structures made in accordance with the invention as compared to more common OTFT structures.

FIG. 4 shows measurements of Hole mobility (un), H values, on/off ratios (ION/OFF), and threshold voltage (Vr) for dielectric structures made in accordance with the invention as compared to more common OTFT structures.

FIG. 5 shows measurements of leakage current for bi-layered and tri-layered dielectrics made in accordance with the invention as compared to more common OTFT structures.

FIG. 6 shows alternative geometries of the bi-layered dielectric based OTFT structure shown in FIG. 1, in accordance with further embodiments of the present invention.

FIG. 7 shows A) chemical structures of TPCL, PVAc and PLA, and B) Top Gate Bottom Contact (TGBC) thin film transistor architecture using a tri layer dielectric.

FIG. 8 shows output and transfer curves for both Bi and Tri layer dielectrics (Bi-and Tri-layer thin film transistors (TFTs)) using single walled carbon nanotubes as the semiconductor and a V_{sd} of −1 V.

### DETAILED DESCRIPTION

One or more currently preferred embodiments have been described by way of example. It will be apparent to persons skilled in the art that a number of variations and modifications can be made without departing from the scope of the invention as defined in the claims.

### Multi-Layered Polymer Constructions

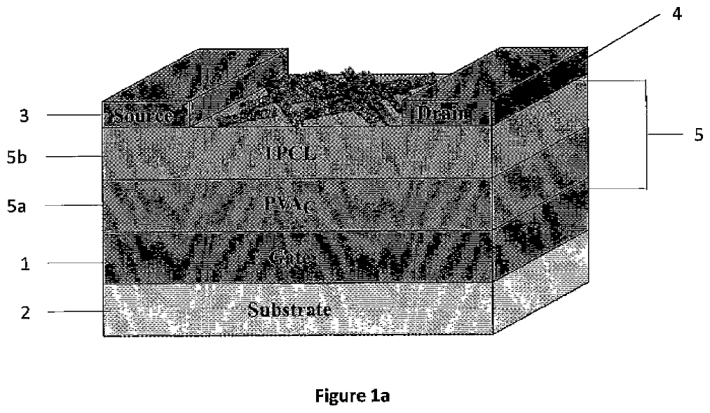

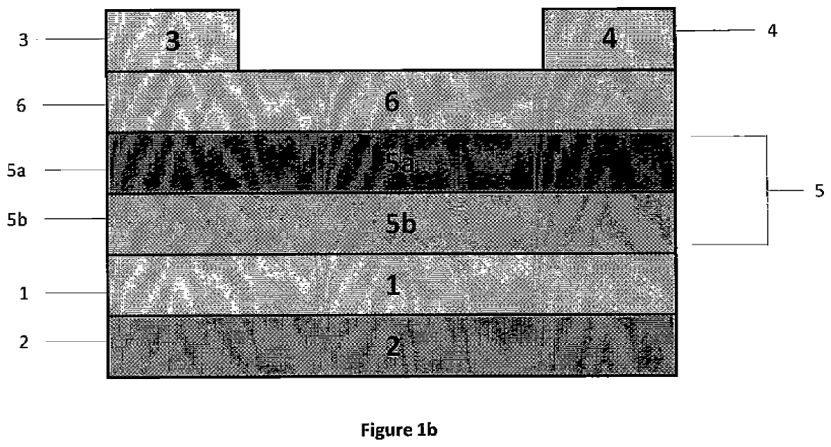

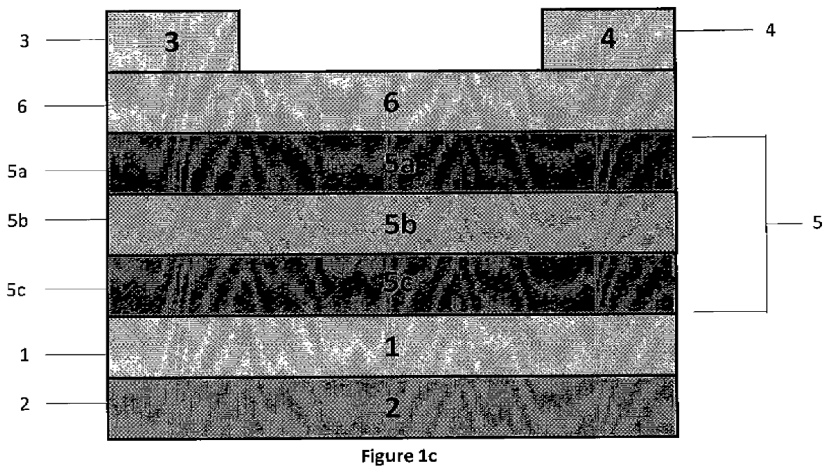

Limitations in existing OTFT capabilities are overcome through the novel combination of multiple dielectric materials in a layered structure. FIG. 1 shows a representation of an OTFT structure made in accordance with the invention. The OTFT has many common characteristics of bottom gate top contact (BGTC) OTFTs, including a gate (1) as the bottom layer adjacent the substrate (2), and a source (3) and drain (4) element at the top of the OTFT. However, unlike existing OTFTs, embodiments of the invention comprise a multiple dielectric layer (5) made up of different dielectric materials, rather than a single dielectric material.

The layering of differing dielectric materials permits greater adaptability of OTFTs. It further enables the negative aspects of some dielectric materials, such as gate leakage, low-k properties, unfavorable surface chemistry, or moisture sensitivity, to be reduced such that they are suitable for use in a wider range of applications.

In an embodiment of the invention, the multiple dielectric layer (5) is made up of a mix of organic dielectric materials. In a preferred embodiment, PVA is used as a dielectric, and its dielectric properties are improved by combining it with a second dielectric that acts to protect it from water exposure. In certain embodiments, the addition of the second dielectric layer also changes the surface chemistry from hydrophilic to hydrophobic. This is especially helpful in an OTFT when depositing the next layer, which will form better on hydrophobic surfaces. This can lead to improved OTFT performance, and better manufacturability of the device. In a particularly preferred embodiment, the PVA layer is further protected by first cross-linking PVA with cellulose nanocrystals.

A particularly preferred embodiment of the invention is exemplified in FIG. 1, where the multiple dielectric layer is comprised of a crosslinked PVA+Cellulose Nanocrystal (PVAc) layer (5a) disposed adjacent to the gate (1) components of the BGTC OTFT, and a toluene diisocyanate-terminated polycaprolactone (TPCL) layer (5b) is disposed between the PVAc layer (5a) and the source (3) and drain (4).

In a further particularly preferred embodiment, the PVAc layer (5a) is thermally cross-linked to the TPCL layer (5b).

Without being limited by any particular mechanism, it is believed that in this particularly preferred embodiment the PVAc layer (5a) has limited exposure to moisture, which reduces gate leakage that would otherwise be present in an OTFT where the sole dielectric was PVAc. It is believed that the layering of the multiple dielectric layer (5) permits a high-k polymer dielectric to be covered with a thin-film of a low-k material and thereby reduces the dipolar disorder at the dielectric/organic semiconductor interface, reducing charge trapping and the leakage current, all while preserving the large capacitance values obtained from high-k polymer dielectrics.

Alternative embodiments of the invention can utilize varying combinations high-k and low-k dielectrics, of either organic or inorganic nature, so as to optimize the desired characteristics of the resulting multiple dielectric layer (5).

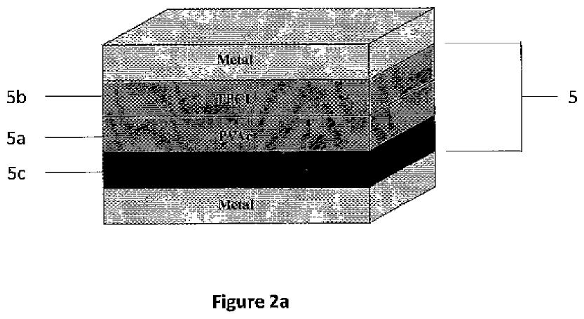

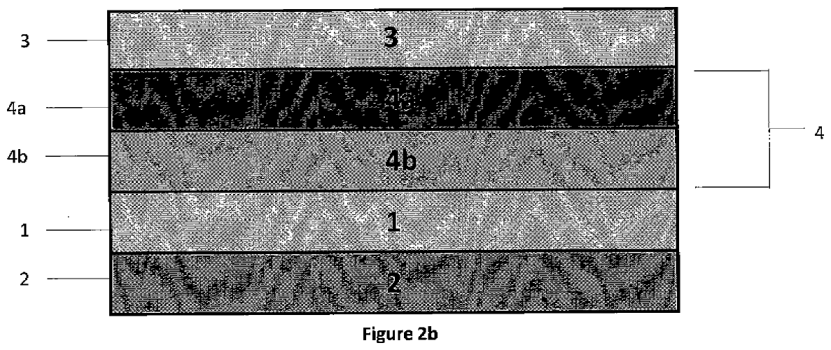

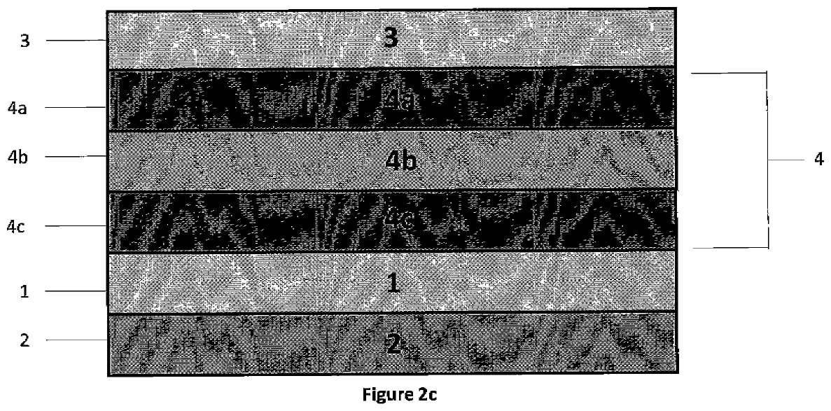

Benefits of the invention are also available through further layering of dielectric materials. As shown in FIG. 2, a tri-layer of dielectric materials can act to further minimize any negative aspects of a particular dielectric such as low-k or undesired gate leakage. In a preferred embodiment, the multiple dielectric layer (5) is comprised of a central PVAc layer (5a), with a TPCL layer (5b) applied adjacent to a first side of the PVAc layer (5a), and a poly (lactic acid) (PLA) layer (5c) applied adjacent to a second side of the PVAc layer (5a).

Without being limited by any particular mechanism, it is believed that in this tri-layer embodiment of the invention, the use of a PLA layer (5c) and TPCL layer (5b) (both of which are low-k dielectrics) to encompass a central high-k PVAc layer (5a) further isolates the

PVAc layer (5a), minimizing the opportunity for dipolar disorder at the dielectric/organic semiconductor interface, and further reducing charge trapping and leakage current.

In a particularly preferred embodiment, the use of a multiple dielectric layer (5) permits the creation of an electronic component, for example but not limited to a sensor, exhibiting high-k, low leakage current, and no hysteresis, from otherwise unsuitable organic dielectrics. This provides an electronic component (e.g. a sensor) that is highly flexible and capable of being processed using a variety of substrate types (including rigid and flexible substrates) without need for costly or complex manufacturing equipment. In a particularly preferred embodiment, the dielectric materials found in the multiple dielectric layer (5) are all non-toxic and biodegradable, making this OTFT design desirable for use in food packaging.

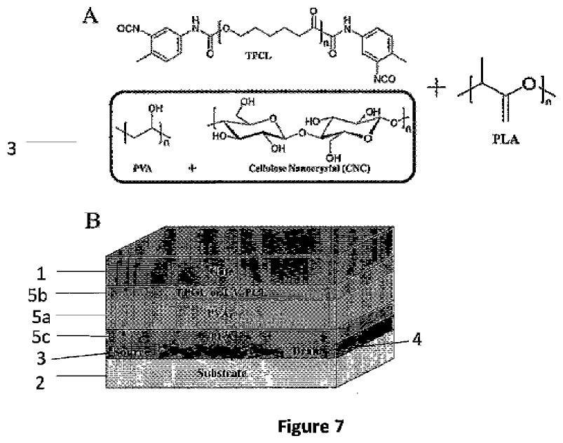

Another tri-layer embodiment of the invention is illustrated in FIG. 7, where the multiple dielectric layer is comprised of a central PVAc layer (5a), with a TPCL or UV-PCL layer (5b) applied adjacent to a first side of the PVAc layer (5a), and a PLA layer (5c) applied adjacent to a second side of the PVAc layer (5a). The TPCL or UV-PCL layer (5b) is disposed adjacent to the gate (1) components of a TGBC thin film transistor, and the PLA layer (5c) is disposed between the PVAc layer (5a) and the source (3) and drain (4), with the substrate (2) as the bottom layer.

### Examples of Beneficial Properties Over Existing OTFTs

When dielectrics are layered in accordance with this invention, the beneficial properties of high-k dielectrics remain available, while the commonly associated limitations (such as excessive gate leakage and sensitivity to moisture) that prevent high-k dielectrics from seeing wide-spread adoption in OTFTs are minimized. The result is an optimized dielectric component of the OTFT.

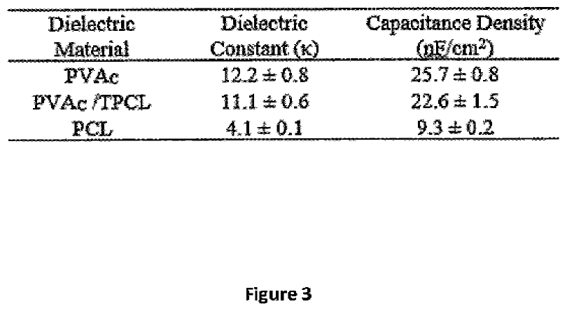

The beneficial properties from use of a multiple dielectric layer (5) in accordance with the invention can be seen in FIG. 3, where the dielectric constant and capacitance density of various OTFTs are compared. As can be seen from FIG. 3, a layered dielectric constant done in accordance with the invention (PVAc/TPCL) maintains the high-k and high density values found in OTFTs using only PVAc as a dielectric. However, this layered dielectric structure minimizes the downsides that would exist from using just PVAc as the dielectric material.

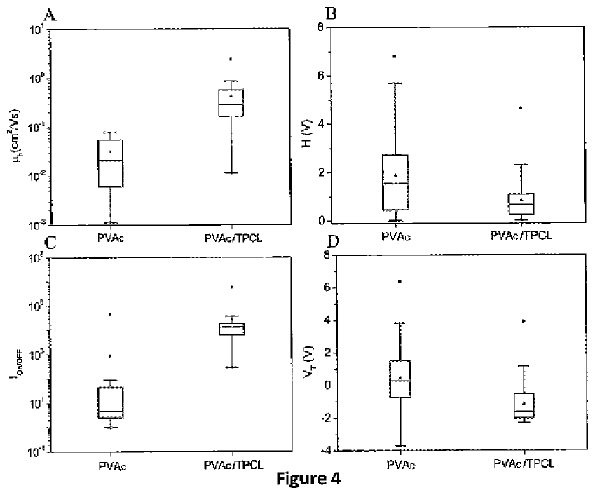

FIG. 4 highlights additional benefits from use of the invention, including improved values for hole mobility (μₕ), H values, on/off ratios (I_{ON/OFF}). And threshold voltage (V_{T}). Specifically, embodiments in accordance with the invention had much greater hole mobility, dramatically reduced H, improved I_{ON/OFF}, and only a minor shift in V_{T}. In addition, it was observed that embodiments of the invention provided improved performance due to favourable surface chemistry and more reproducible values, suggestive of a more reliable

OTFT manufacturing process.

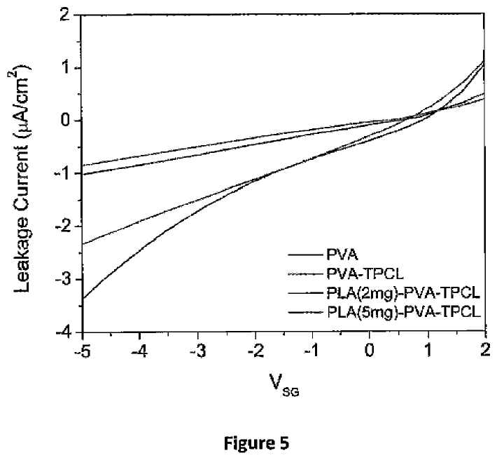

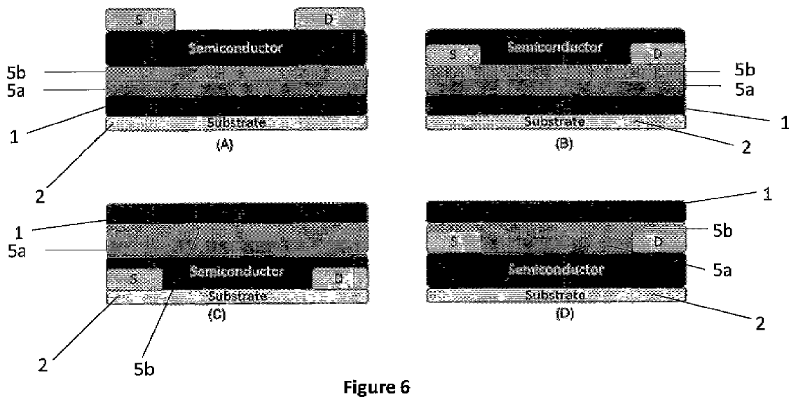

With regard to tri-layered dielectrics, FIG. 5 highlights a stability in leakage current in the tri-layered dielectric embodiment of the invention (PLA-PVA-TPCL), which was improved over that of a bi-layered dielectric embodiment (PVA-TPCL) and greatly improved over a standard, mono dielectric design (PVA).

### Methods of Manufacturing Suitable Multi-Layered Dielectric Polymers

The following examples illustrate methods of manufacturing OTFTs in accordance with the invention. The skilled person would understand what modification would be required to accommodate different dielectric materials when generating the multiple dielectric layer (5) component from a different combination of dielectric materials. Choice of preferred dielectric materials are dependent upon the intended use and desired properties of the sensor.

### TPCL Synthesis

The synthesis of difunctionalized diisocyanate polycaprolactone was conducted as described by Prisco et al (Preparation, Physico-Chemical Characterization, and Optical Analysis of Polyvinyl Alcohol-Based Films Suitable for Protected Cultivation. J. Appl. Polym. Sci. 2002, 86 (3), 622-632. https://doi.org/10.1002/app.10912).

Polycaprolactone diol (PCL, 0.98 g, 0.5 mmol) was dissolved in chloroform (10 mL) and placed under nitrogen atmosphere. Tolylene-2,4-diisocyanate (0.97 g, 5.6 mmol), dissolved in chloroform (3 mL), was added to the PCL solution. The reaction mixture was refluxed at 65° C. for 5 hours. The chloroform was evaporated under reduced pressure, and the obtained viscous oil was washed three times with petroleum ether. The product was dissolved in dichloromethane (2 mL) and precipitated in petroleum ether (50 mL). The precipitation was repeated twice.

The product (0.9 g) was obtained as a viscous oil, which was dried in vacuo. ¹H-NMR (400 MHz. CDCl₃): 1.30, 1.39, and 1.64 (—CH₂—); 2.27 (—CH₃); 2.31 (—CH₂—); 3.88 and 4.06 (—CH₂—O—); 6.56, 6.77, and 7.08 (C—H, arom) ppm. FT-IR: 1220 (C-N), 1553 (N-H), 1724 (C═O), and 2270 (N═C—O) cm-¹.

### Preparation of Dielectric and Semiconductor Materials

PVAc dispersions were prepared in ambient conditions according to Tousignant et al. (Improving Thin-Film Properties of Poly (Vinyl Alcohol) by the Addition of Low-Weight Percentages of Cellulose Nanocrystals. Langmuir 2020, 36 (13) https://doi.org/10.1021/acs.langmuir.0c00068).

A final concentration of 80 mg/ml PVA and 0.75 wt % CNCs. Briefly, 320 mg of PVA was dissolved in 2400 μL of distilled water at 90° C. and filtered using a 0.45 μm filter, after which 1650 μL of a 2 wt % dispersion of CNCs in water was added. TPCL solutions in anhydrous toluene were prepared at concentrations of 10, 4 and 2 mg/ml in a nitrogen-filled glovebox. PCL 80K MW was dissolved at 35 mg/ml. PCL was weighed under ambient environment and dissolved in toluene.

Ultrapure semiconducting-enriched dispersions of single-walled carbon nanotubes (sc-SWNTs) were prepared with a poly (carbazole-alt-co-fluorene) polymer (PCF) in toluene according to Rice et al. (Polycarbazole-Sorted Semiconducting Single-Walled Carbon Nanotubes for Incorporation into Organic Thin Film Transistors. Adv. Electron. Mater. 2019,5 (1), 1-11. https://doi.org/10.1002/aelm.201800539)

The synthesis of PCF (Mn=65 kDa, Ð=2.7) was also performed according Rice et al., with dispersions prepared using plasma grown SWCNTs (Batch: RNB781-120, diameter: 0.9-1.5 nm) purchased from Raymor NanoIntegris. The PCF-SWCNT dispersion was not filtered to remove excess polymer prior to fabricating OTFT devices, with concentration of sc-SWCNTs adjusted so that the peak at 937 nm had an absorbance value of 2.0 a.u (Figure S3).

### Thin Film Fabrication and Characterization

A Laurell WS-650-23 spin coater was used to deposit the PVAc and PCL films. A specialty coating systems G3P-8 spin coater was used to deposit the TPCL films. PVAC, PVAc/TPCL, and PVAc/PCL films were deposited on 1 in² glass substrates. The substrates were cleaned in a bath sonicator for 5 minutes using detergent, distilled water, acetone, and methanol, sequentially. The PVAc films were deposited by spin coating (200 μL) at 3000 RPM for 90 s under ambient conditions, then annealed under vacuum at 150° C. for 1h to remove excess moisture. PCL layers were deposited (200 μL) at 2000 RPM for 90 s under ambient conditions. TPCL layers were deposited (200 μL) at 2000 RPM for 60 s in an inert environment, then annealed for 15 minutes at 200° C. under vacuum to thermally crosslink the TPCL to the PVAc film.

### Crosslinking

Embodiments of the invention described herein additionally involve a process for preparing a multi-layer dielectric which comprises crosslinking the solution-processable polymers. For example, the method may comprise thermally crosslinking the low-k dielectric material with the high-k dielectric material. In embodiments, this may involve the crosslinking of a toluene diisocyanate-terminated polycaprolactone (TPCL) layer with the hydroxyl groups of a poly (vinyl alcohol)/cellulose nanocrystal (CNC) blended dielectric (PVAc).

In this non limiting example, a low-k TPCL layer is crosslinked on top of a high-k blend of PVA and CNCs (PVAc). The TPCL layer was thermally crosslinked with hydroxyl groups in the PVAc blend at the bilayer interface after film deposition. Optical profilometry and microscopy studies were performed to determine the optimal TPCL concentration to yield consistent thin-films. Metal-insulator-metal (MIM) capacitors were fabricated with and without the TPCL layer and characterized under ambient conditions and after 30 minutes of exposure to 99% relative humidity (RH). Incorporation of the TPCL layer significantly decreased moisture sensitivity compared to neat PVAc. Thermally crosslinking the TPCL polymer with the hydroxyl groups of PVAc enables annealing above the Tₘ of PCL as the crosslinked TPCL films can no longer move freely on the surface of the PVAc film and self-aggregate. In certain preferred embodiments, which are non limiting, the crosslinking can be carried out at from 150° C. to 350° C., in particular from 150° C. to 250° C., preferably about 200° C.

### Tri layer Results

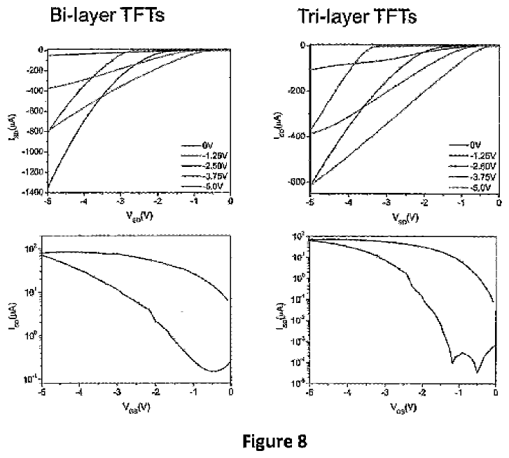

FIG. 8 and Tables 1 and 2 below show the results of testing performance of the tri layer architecture described herein. Higher mobilities were observed with a tri layer architecture, due at least in part to eliminating the interactions between PVA and the SWCNTs. The tri layer architecture also allows for devices to be fabricated in a bottom gate top contact (BGTC) architecture without sacrificing performance. The inventors also observed that the PLA is a more compatible surface for the PVA deposition, which leads to more functioning devices.

TABLE 1
Bi and Tri layer dielectric TGBC TFTs
fabricated on an OTS treated substrate

| Layers and | Hole Mobility | | |
|---|---|---|---|
| drops | (cm\hat{ }2/Vs) | Ion/off | Vt (V) |
| Tri | 45.91 ± 18.44 | 10\hat{ }6 | −2.60 ± 0.47 |
| Bi | 2.56 ± 1.71 | 10\hat{ }4 | −3.31 ± 0.29 |

TABLE 2
Dielectric properties of tri-layer dielectric materials at 10 Hz

| | Dielectric | Capacitance |
|---|---|---|
| Dielectric | Constant | Density |
| Material | [κ] | [nF/cm²] |
| PVAc/TPCL | 11.67 | 24.15 |
| PLA/PVAc/TPCL | 8.88 | 21.034 |

What is claimed is:

1. A polymer dielectric comprising a multi-layered structure containing at least two different dielectric materials, wherein the dielectric materials comprise biodegradable organic dielectric materials.

2. The polymer dielectric of claim 1, containing two or three different dielectric materials.

3. The polymer dielectric of claim 1 or 2, wherein the multi-layered dielectric contains at least one low-k dielectric material and at least one high-k dielectric material.

4. The polymer dielectric of any one of claims 1 to 3, wherein the biodegradable organic dielectric materials are crosslinked at an interface of the material interface.

5. The polymer capacitive sensor of any one of claims 1 to 3, wherein the dielectric is a capacitor or transistor, or a polymer capacitive sensor.

6. An organic thin-film transistor (OTFT) comprising:
a. a substrate component;
b. a gate component;
c. a multi-layered dielectric component;
d. a source component; and
e. a drain component.

7. A capacitor comprising:
a. a substrate component;
b. a bottom electrode component;
c. a multi-layered dielectric component; and
d. a top electrode component.

8. The OTFT of claim 6 or capacitor of claim 7, wherein the multi-layered dielectric component is comprised of at least two different dielectric materials;

9. The OTFT or capacitor of any one of claims 6 to 8, wherein the multi-layered dielectric component is comprised of at least one high-k dielectric material and at least one low-k dielectric material.

10. The OTFT or capacitor of any one of claims 6 to 9, wherein the multi-layered dielectric component consists of only organic dielectric materials;

11. The OTFT or capacitor of any one of claims 6 to 10, wherein the multi-layered dielectric component consists of only biodegradable materials;

12. The OTFT or capacitor of any one of claims 6 to 11, wherein the multi-layered dielectric component comprises:
a. a poly (vinyl alcohol)/cellulose nanocrystal blended dielectric (PVAc) layer deposited above the gate component or the substrate component; and
b. a toluene diisocyanate-terminated polycaprolactone (TPCL) layer deposited above the PVAc layer.

13. The OTFT or capacitor of claim 12, wherein the PVAc layer and TPCL are thermally cross-linked to one another.

14. The OTFT or capacitor of any one of claims 6 to 11, wherein the multi-layered dielectric component comprises:
a. a poly (vinyl alcohol)/cellulose nanocrystal blended dielectric (PVAc) layer, having a first surface and a second surface;
b. a toluene diisocyanate-terminated polycaprolactone (TPCL) layer disposed at said first surface; and
c. a poly (lactic acid) (PLA) layer disposed at said second surface.

15. The OTFT or capacitor of claim 13, wherein the TPCL layer is deposited above the PVAc layer, and the PVAc layer is deposited above the PLA layer.

16. The OTFT or capacitor of claim 13 or 14, wherein the PVAc layer and TPCL are thermally cross-linked to one another.

17. A method for preparing a multi-layer dielectric for an organic thin-film transistor (OTFT) or capacitor, wherein
a high-k dielectric material layer is deposited above a gate component or a substrate component of the OTFT or capacitor;
a low-k dielectric material layer is deposited above the high-k dielectric material layer; and
the low-k dielectric material is crosslinked with the high-k dielectric material.

18. The method of claim 17, wherein the high-k dielectric material is a poly (vinyl alcohol)/cellulose nanocrystal blended dielectric (PVAc) and the low-k dielectric material is a toluene diisocyanate-terminated polycaprolactone (TPCL) and the TPCL layer is crosslinked with the PVAc material via hydroxyl groups of the PVAc material.

19. The method of claim 17 or 18, wherein the low-k dielectric material layer is crosslinked on top of the high-k dielectric material at a layer interface after deposition.

20. The method of any one of claims 17 to 20, wherein the crosslinking is carried out at from 150° C. to 350° C., or from 150° C. to 250° C.

21. The method of claim 20, wherein the crosslinking is carried out at about 200° C.
